(19) United States
(12) Patent Application Publication
(10) Pub. No.: US 2026/0368965 A1
(43) Pub. Date: Nov. 19, 2026

(54) Patent Drawing Generation and Assessment from Base File

(71) Applicant: Thomas Tatonetti, Brooklyn, NY (US)

(72) Inventor: Thomas Tatonetti, Brooklyn, NY (US)

(21) Appl. No.: 19/334,887

(22) Filed: Sep. 21, 2025

Related U.S. Application Data
(63) Continuation of application No. 19/253,921, filed on Jun. 29, 2025.
Application No. 19/253,921 is a continuation-in-part of application No. 19/207,723, filed on May 14, 2025.
(60) Provisional application No. 63/828,179, filed on Jun. 22, 2025.

(51) Int. Cl. G06T 11/60; G06F 30/12

(52) U.S. Cl. CPC G06T 11/60; G06F 30/12

(57) ABSTRACT

An automated and artificial intelligence (AI) enhanced design patent drawing conversion system (hereinafter “conversion system”) is configured to receive one or more image files, such as a three-dimensional CAD (Computer-Aided Design) file including STP., STL. and the like and output usable patent drawings. A user uploads their CAD file at their local computing device via some local application or web browser accessing a URL (uniform resource locator), which the application service then transmits to a remote drawing conversion service, which may be the same or distinct from the application service. The conversion software processes the three-dimensional CAD file by re-positioning the object within the CAD file and manipulating the object's angle at that same position. At each position and at each angle, the conversion system creates a two-dimensional file, such as a DXF (Drawing Exchange Format) file, PDF file, JPG file, and others that are then usable as patent drawings.

### CROSS-REFERENCES TO RELATED APPLICATIONS

This Non-Provisional Utility Patent Application claims the benefit of and priority to U.S. Provisional Patent Application Ser. No. 63/828,179, filed Jun. 22, 2025, entitled “AI-Driven System for Generating Patent-Compliant Drawings from CAD Models,” the entire contents of which is hereby incorporated herein by reference.

This Non-Provisional Utility Patent Application is Continuation Application that claims the benefit of and priority to U.S. Non-Provisional Patent Application Ser. No. 19/253,921, filed Jun. 29, 2025, which is a Continuation-In-Part (CIP) application that claims the benefit of and priority to US Non-Provisional Patent Application Ser. No. 19/207,723, filed May 14, 2025, entitled “Automated Generation of Patent Drawings,” the entire contents of both applications of which are hereby incorporated herein by reference.

### BACKGROUND

Patent drawings are often expensive and cause delay in a law firm's or Applicant's ability to prepare and file a patent application. Strict requirements brought about by jurisdictional patent offices require specific procedures be followed when generating these drawings, which often take hours and days for dedicated draftperson professionals to prepare.

### SUMMARY

An automated and artificial intelligence (AI) enhanced design patent drawing conversion system (hereinafter “conversion system”) is configured to receive one or more image files, such as a three-dimensional CAD (Computer-Aided Design) file including STP., STL. and the like and output usable patent drawings. A user uploads their CAD file at their local computing device via some local application or web browser accessing a URL (uniform resource locator), which the application service then transmits to a remote drawing conversion service, which may be the same or distinct from the application service. The conversion software processes the three-dimensional CAD file by re-positioning the object within the CAD file and manipulating the object's angle at that same position. At each position and at each angle, the conversion system creates a two-dimensional file, such as a DXF (Drawing Exchange Format) file, PDF file, JPG file, and others that are then usable as patent drawings for a user's patent application.

Multiple variations of the drawings can be output, such as one version with tangent/contour lines, a version without tangent/contour lines, and one version with AI drawing enhancements. The AI-enhanced patent drawings will be based on a proprietary model generated by patent drawings from worldwide patent databases, which may then be further segregated by country to satisfy each country's proprietary drawing preferences and requirements. The generated patent drawings may then be processed by the AI model to make additional modifications to the output patent drawings to more accurately satisfy each country's respective laws. For example, the original output drawings from the CAD file may be missing a line, include unnecessary or unwanted insignia, such as company logos, or have other minor issues that the AI-enhanced engine can correct. Lines can be drawn that the failed output failed to include, such as because the CAD file was incorrect or the conversion system somehow made a conversion error. Furthermore, countries like the United States that require line shading can be learned by the AI model and then intelligently and strategically applied by the AI engine. Such techniques will leverage AI with modifiable drawing software, such as CAD software (e.g., AutoCAD®, Solidworks®), or two-dimensional software like Adobe Illustrator®, Corel Draw®, Visio®, etc.

### DESCRIPTION OF THE DRAWINGS

FIG. 1 shows an illustrative environment in which a CAD file is converted into patent drawings;

FIG. 2 shows an illustrative environment in which CAD files are run through a dedicated AI engine to create AI-enhanced patent drawings;

FIG. 3 shows an illustrative schema of focus points for developed design patent drawings, whether AI-enhanced or not;

FIG. 4 shows an illustrative environment of image files being fed into the AI engine of the drawing conversion service;

FIG. 5 shows an illustrative environment of a CAD filed being converted into patent drawings; and

FIGS. 6 and 7 show illustrative examples of the drawing conversion system re-positioning and centering an uploaded CAD file;

FIGS. 8 and 9 show illustrative examples of the drawing conversion system manipulating the three-dimensional object to capture two-dimensional files from various angles;

FIG. 10 shows an illustrative environment in which call-out lines are added to the generated patent drawings;

FIG. 11 shows an illustrative representation of reference numerals being added to the call-out lines and specific components;

FIG. 12 shows an illustrative interactive environment where a user can select which components they want acted upon;

FIG. 13 shows an illustrative environment in which the user provides input to modify or otherwise instruct the AI-engine;

FIG. 14 shows an illustrative flowchart executed by one or more computing devices and/or remote services;

FIG. 15 shows an illustrative environment in which patent drawings are checked for accuracy from another file, such as a three-dimensional CAD file; and

FIGS. 16 and 17 show illustrative diagrams of computer systems that may be used, such as for the user's computing device or remote services.

Like reference numerals indicate like elements in the drawings. Elements are not drawn to scale unless otherwise indicated.

### DETAILED DESCRIPTION

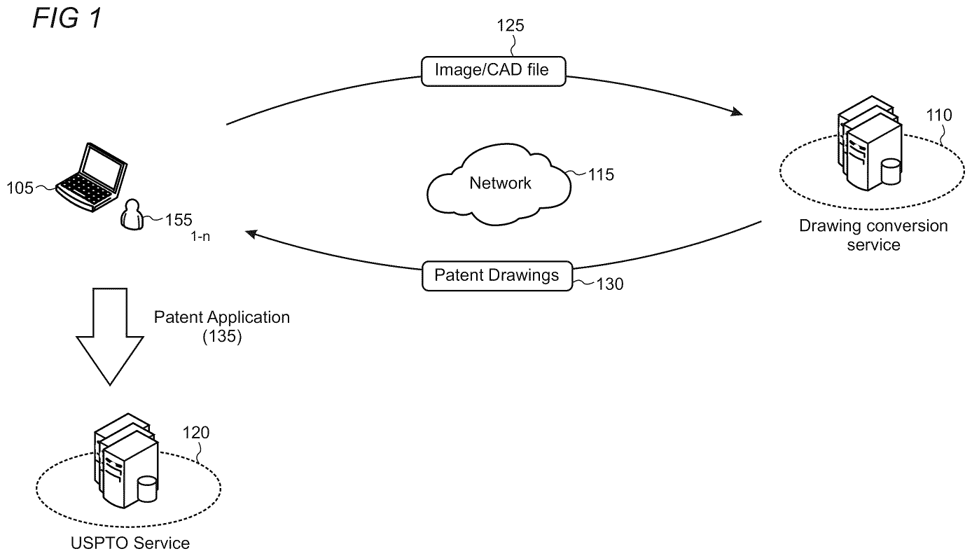

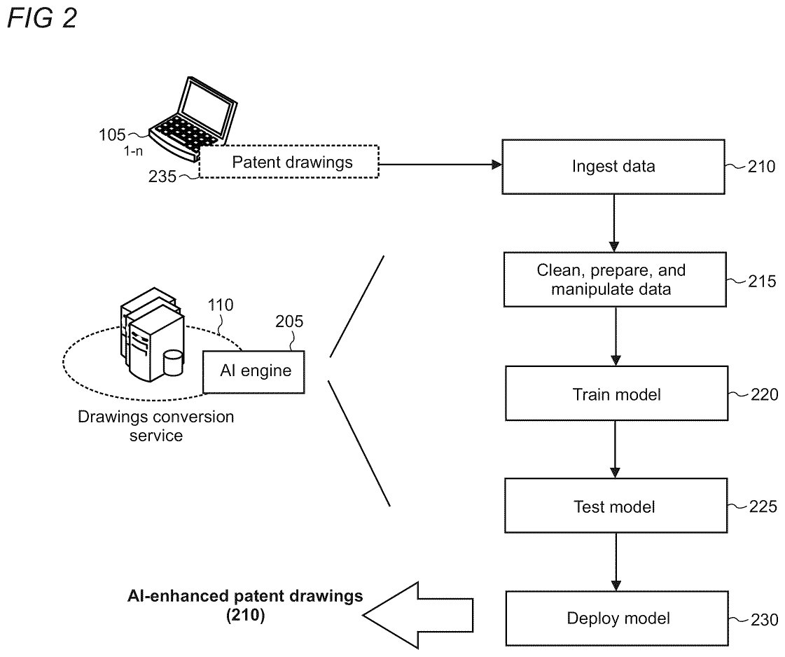

FIG. 1 shows an illustrative example in which a user device 105 transmits an image/CAD file 125, such as a STP., STL. DWG, DXF, IGES, OBJ, SLDPRT, SLDASM, etc. to a drawing conversion service 110. The CAD or image file may be considered the “base” file that is initially uploaded by the user and is subsequently processed. The base file is is automatically transitioned into a patent drawings file 130 so the end user 155 has the requisite drawings to submit with a patent application 135 to the patent office, such as a USPTO (United States Patent and Trademark Office) service 120. In some implementations, a first image file transmitted to the drawing conversion service my convert the received file into a more suitable file for AI processing. For example, a CAD file may be converted into a DXF (Drawing Exchange Format) file for more suitable processing. Other conversions of an initial file into a used file are also possible that perform the functions described herein. In some implementations, the drawing conversion service 110 may be set up to submit a patent application for a user upon the user's request. Furthermore, in some implementations, the drawing conversion service may be configured to create the written specification and claims section of the patent application, namely for design patents given their short description. For example, the drawing conversion service knows which views it is ordering for the design patent drawings, so creating the specification and claims, based on some input from the user, like the inventors' names, title of the product, etc., can be used to generate the full application for submission to the USPTO or presentation or transmission to the end user.
FIG. 2 shows an illustrative example in which the drawing conversion service 110 receives the patent drawings 235 and runs it through the AI (Artificial Intelligence)-engine 205 to develop and deploy a working AI model. Multiple examples of design patent drawings, whether issued patents, published patents, or otherwise just patent drawing examples, are fed into the AI engine. Utility and design patent drawings can be fed into the AI engine.

Also, patent drawings from different patent offices can also be input, in which multiple models developed for each respective patent office is utilized for sets of patent drawings. So, the system may work for patent offices worldwide. For example, patent drawing rules in the United States may be different from those in the European Union, Australia, United Kingdom, South Korea, etc. Training a model for the EU may require uploading EU patent drawings to train the model and then have the AI engine create patent drawings based on that trained data set. This can occur for all patent offices worldwide. Thus, receiving and segregating the learned models based on jurisdictional patent office and further by utility or design patent model may provide enhanced accuracy for the model. Depending on a user's request, suitable patent drawings may be automatically developed via the AI-engine to satisfy each patent office's requirements.

The AI engine 205 ingests the data (e.g., patent drawings) and then may clean, prepare, and manipulate the data. For example, the data may be randomized, to reduce the possibility of an order affecting the machine learning process, and separated, between a training set for training the model and a testing set for testing the trained model. Other forms of data manipulation may be performed as well, such as normalization, error correction, and the like. The deployed model may take a submitted set image file, such as an already generated set of patent drawings 130 (FIG. 1) or a CAD file, and output AI-enhanced patent drawings 210 for the user 155.

The AI engine 205 trains and tests the model, respectively. The model training may be used to incrementally improve the model's ability to create accurate patent drawings. The model training may use the features contained in the data to form a matrix with weights and biases against the data. Random values within the data may be utilized to attempt prediction of the output based on those values. This process may repeat until a more accurate model is developed which can generate correct outputs.

The model may subsequently be evaluated to determine if it meets some accuracy threshold (e.g., 90%), and then the predictive model will be deployed to generate AI-enhanced patent drawings 210.

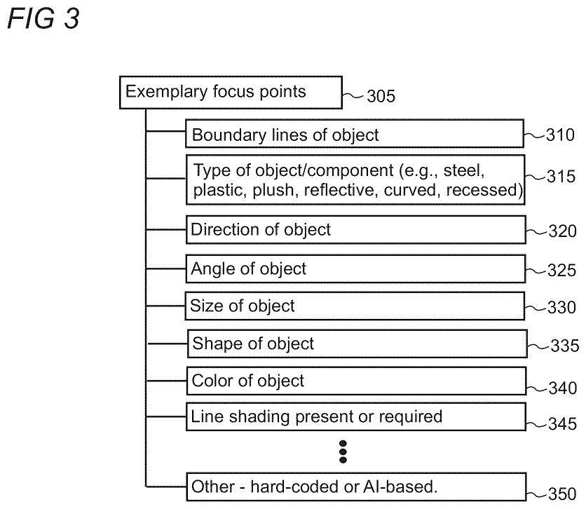

While the AI engine 205 is one method by which the remote drawing conversion service 110 can develop pattern recognitions among the patent drawing data, other methods of pattern recognition are also possible. Such as using hard-coded methods or rules in an algorithm which creates identifies specific features of an object's image file to generate proper patent drawings, whether design or utility. Hard coded rules may include identifying trademarks or other words that typically are not included in patent drawings, namely design patent drawings. Hard-coded rules may be FIG. 3 shows an illustrative schema of focus points that the drawing conversion system may consider when generating the patent drawings, whether AI-enhanced or the non-AI patent drawings based on the image/CAD file 125. For example, the boundary lines of an object 310, type of object/component 315, direction of object 320, angle of object 325, size of object 330, shape of object 335, color of object 340, line shading present or required 345, and other considerations that may be hard-coded into the system or identified by the AI-engine, 350. Each of these features may be identified by the AI engine when generating design patent drawings for a given object. The AI-engine may identify specific file types and alter the strategic output. For example, greyscale images may be generated for objects that do not have a hard or clear texture-like plush material or curvy objects. In that regard, the drawing conversion service may either be hard coded to identify such objects and adapt accordingly, or otherwise the AI engine my autonomously identify such texture to output appropriately.

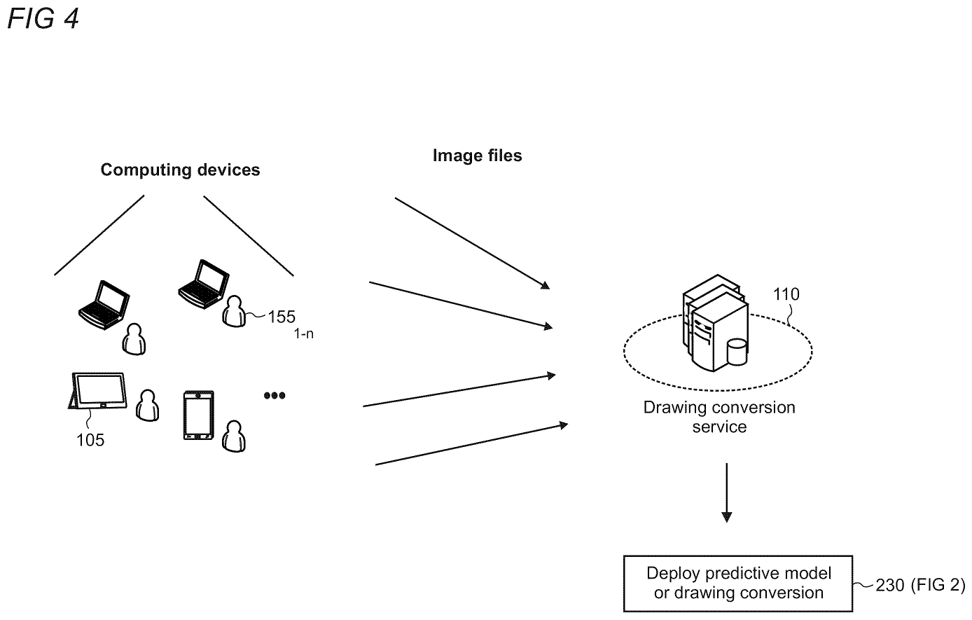

FIG. 4 shows an illustrative environment in which computing device 155 can leverage the drawing conversion service 110 by uploading some image files of their desired product. For example, users 155 may upload CAD drawings (e.g., a STP., STL., etc. files), PNG, JPG, or other image file that the drawing conversion service can load into its trained and deployed model 230 to generate AI-enhanced patent drawings 210. Although not shown, the user can select whether they'd like utility or design patent drawings, and for which country they wish to have the drawings made. This way, design patent drawings for, for example, Japan, are properly created.

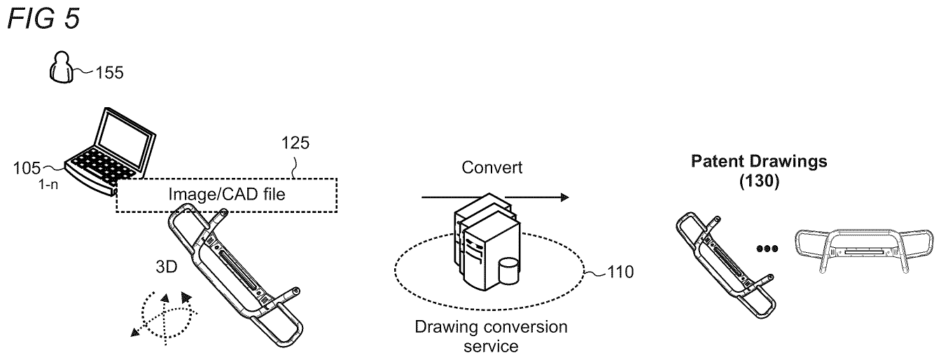

FIG. 5 shows an illustrative environment in which a user 155 uploads an image/CAD file 125 to the drawing conversion service 110 which automatically creates and outputs patent drawings 130. Such processing can, in typical implementations, take anywhere from seconds or minutes, depending on the size and complexity of the file and the available resources of the drawing conversion system. So, simple files may be completed in seconds and more complex files may take minutes.

Such a system creates a streamlined patent drawing generation service by which users 155 no longer need to wait days or weeks for patent drawings 130 to be hand drawn and risk human error, while simultaneously saving costs. The patent drawings are black and white line drawings of the various contours of the object within the file. So, the generated file may include the boundary and various contour lines of the created design. As shown in FIG. 5, an uploaded CAD file 125 can be three-dimensional in nature, thereby making it unusable for patent drawings without downstream processing. Even if a human were to perform the task of converting the three-dimensional file into a two-dimensional one, the risk of error is omnipresent in various tasks and the output is imperfect. Furthermore, autonomously identifying and selecting which lines to apply, remove, and alter is impossible without and years of training- and even then, mistakes are present. The AI-enhanced drawings is configured with enhanced capabilities and, at times, hard-coded rules to create patent drawings that can even train the best patent draftperson on how to perform their job better.

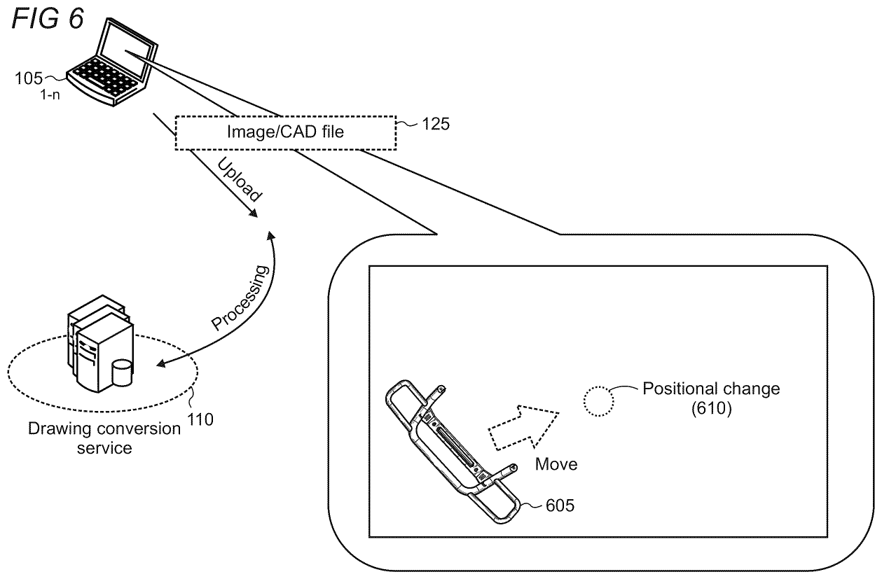

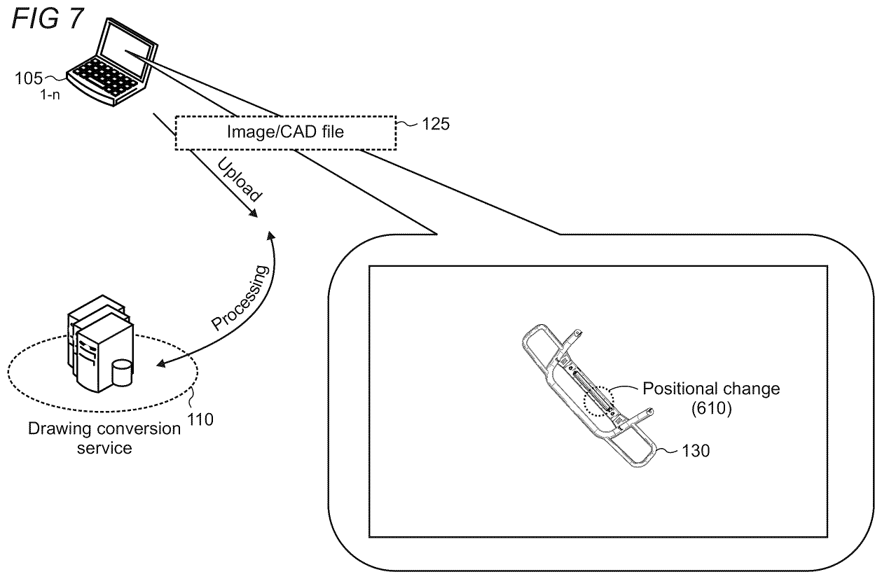

FIGS. 6 and 7 show sequential environments in which an uploaded image/CAD file 125 is initially processed by the drawing conversion service 110, at least according to one embodiment. For example, image files may be prepared according to whatever proprietary procedures or customizations of the creator. Thus, the may can be pre-processed to ensure it is ready for intentional processing, such as by a patent conversion service. In FIGS. 6 and 7, the object 605, from the uploaded image/CAD file 125, is viewable within three-dimensional CAD viewer, such as AutoCAD®, Solidworks®, FreeCAD, etc. The file may be identified by capturing all portions (e.g., lines) of the uploaded file and then positioning it at a specifically desired position of the screen.

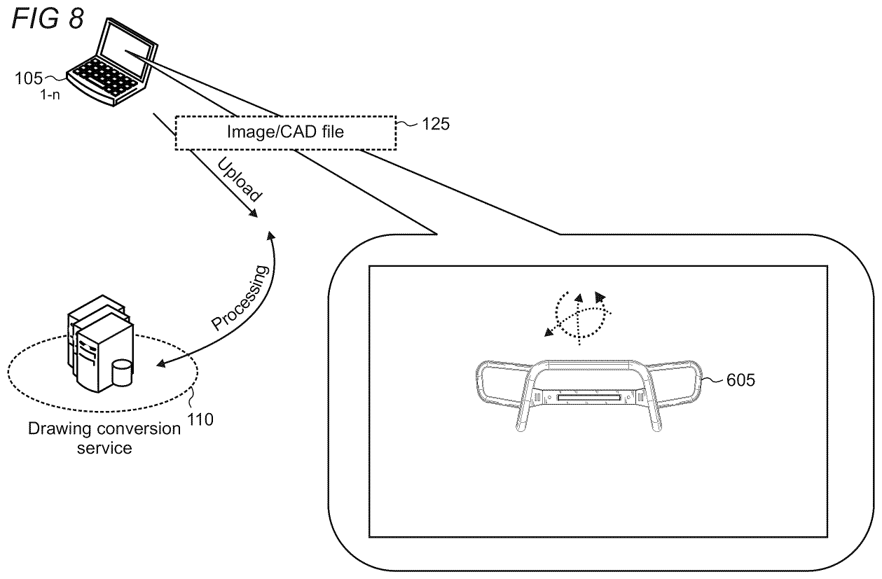

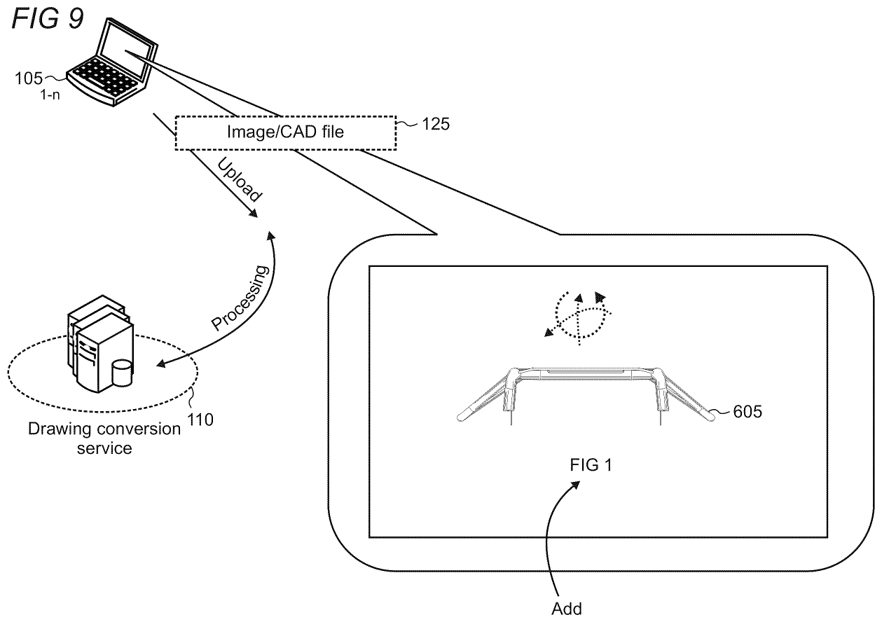

FIG. 8 shows an illustrative environment in which the object 605 has been manipulated to a different perspective for the patent application. FIG. 8 shows a front view whereas FIG. 9 shows a bottom view. The manipulation may be performed by autonomously changing the objects position inside the native software that can open the file. Upon the file being manipulated to a set position (e.g., 90 degrees, 180 degrees, 270 degrees, etc.), the software triggers a ‘save’ command by which the file is saved as a, for example, DXF file.

This process may repeat itself for a series of different file types. For example, a first repositioning and altering of the various views or angles of the presented object may be captured from each angle for a PDF file. Once all of the angles for that particular type of file are generated, the software may re-execute itself to generate a different set of file types, such as greyscale images, vector files, DXF files, a file in which the saved views have tangent lines, a file in which the saved views do not have tangent lines, etc. This way, the software can execute itself more seamlessly so that a series of similar file types are saved together, and then other file types can be saved. This may also be affected by the end user selecting which file types they want before the system starts processing. Such re-processing by the system may also affect how the saved images/views are presented, such as having call out lines added, having reference numerals added, whether cross-sectionals are present, whether exploded views are present, etc. Again, so that like files are generated together in a more coherent manner. Processing and re-processing of the CAD file may be performed in real-time or near real-time so that the user can receive a series of usable files (PDF, DXF, greyscale, etc.) within but a few minutes after they uploaded their CAD file. Such processing and re-processing can apply to the various features and processing techniques discussed herein, including regarding discussions and references to FIGS. 7-13.

Processing and converting of the views and files may also be performed to touch-up, clean-up, or otherwise modify the generated and converted files. For example, line shading may be added, lines may be removed if, for example, excessive lines are present like tangent lines. For example, contour or tangent lines may be excessive in some conversions if there are, for example, curved surfaces. In such situations, some of the tangent or contour lines may be removed to make the generated drawing cleaner. Other modifications may also be performed on the file. For example, if the CAD file includes a description or other information as to what the component is, this can be utilized by the conversion software to put additional details into the generated views. Such additional details may be, for example, the conversion software adding call out lines (with or without reference numerals) to every component that is identified or described in the CAD file. Alternatively, with or without the use of AI, the conversion software may take information from the CAD file so that modifications (additions, deletions, modifications) of the generated line drawing can be modified to better illustrate the component's purpose. For example, openings or holes in a surface may be shown by adding a line downward, or in the direction of the opening/hole.

Surface information about the component may also be utilized, such as a soft or fluffy surface, wooden surface, glossy or glass surface, etc. All of this information can be digested by the software to automatically apply certain modifications to the drawings so the end user has a more accurate and holistic output.

FIG. 9 shows an illustrative environment in which the drawing conversion software adds a figure number to the drawing. So, in this example, “FIG. 1” is added to the drawing, which is then used as a basis for saving the file. This processing is performed for each object manipulation so until the set number of drawings is prepared.

Leveraging the CAD software, the object within the CAD file 125 can be further modified to output greyscale drawings, cross-sectionals, and the like. Put simply, cross-sectional drawings can be generated from every angle of the object. The cross-sectionals can either be set at a center of the object, or, alternatively, at an off-centered position. The off-centered positions may be further be horizontally, vertically, diagonally, or otherwise offset to capture the cross-sectional angle from a desired vantage point.

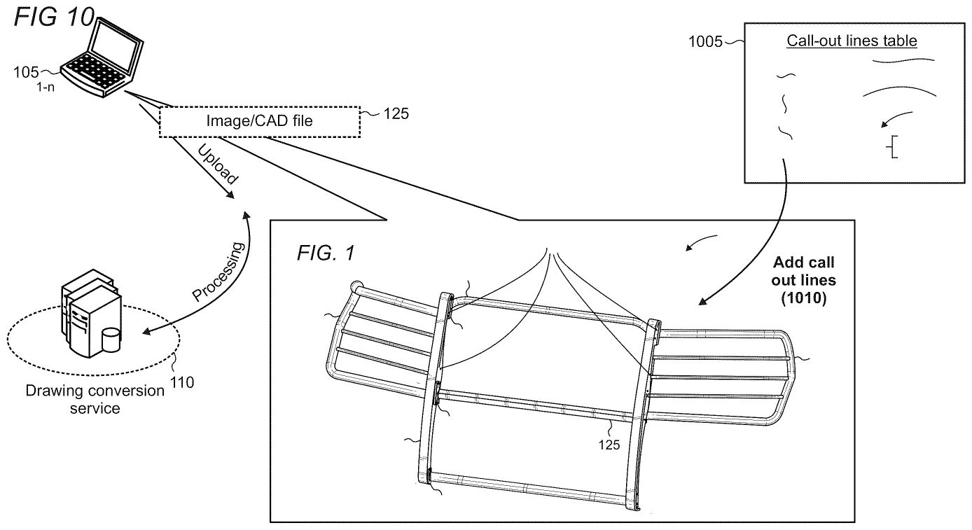

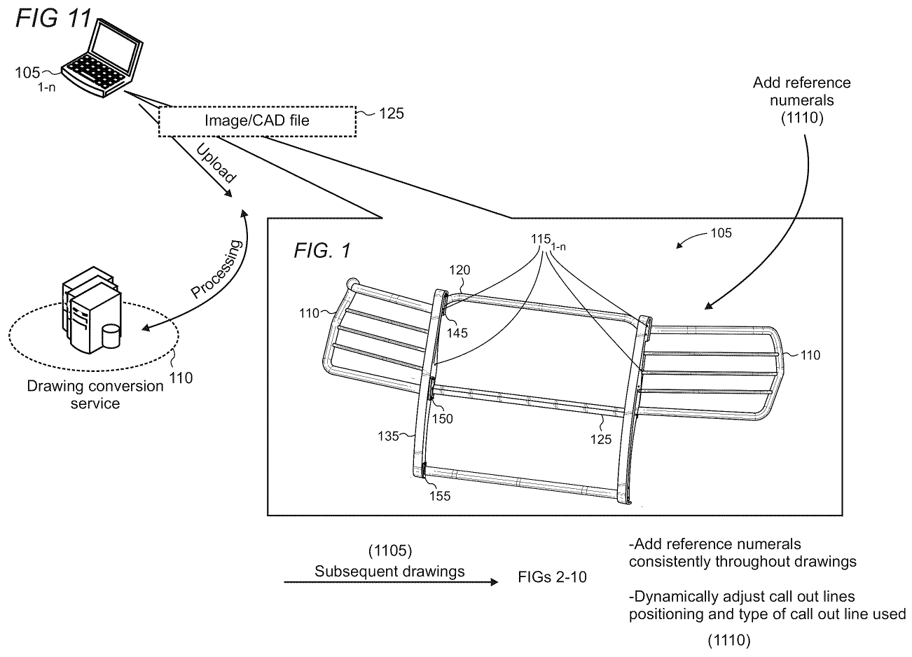

FIG. 10 shows an illustrative environment in which the remote drawing service 110 adds to the generated patent drawing call-out lines to components, as representatively illustrated by reference numeral 1010. The service may utilize an AI-engine that is configured to identify specific components from the generated patent drawing. The call-out line table 1005 shows exemplary lines or references that may be used to call-out a specific component or group of components. The AI-engine may analyze the drawing and identify different components that require a call-out line which will subsequently include a reference numeral (FIG. 11).

The analysis by the AI-engine may be based on digesting prior patent drawings. In this regard, the AI-engine may be trained to identify types of changes between components or lines within a drawing to justify adding call-out lines to components on a patent drawing.

AI can identify edges and lines in black-and-white drawings by leveraging a combination of traditional image processing techniques and advanced machine learning models. Classical methods, such as the Canny edge detector, Sobel operator, and Laplacian filters, work by analyzing gradients in pixel intensity to find areas of rapid change—these changes usually correspond to edges or lines in an image. The Canny method, for example, smooths the image to reduce noise, detects intensity gradients, applies non-maximum suppression to thin out the lines, and finally uses hysteresis thresholding to identify strong and weak edges. These approaches are widely used in technical and engineering contexts where precise line extraction is critical.

Beyond traditional methods, modern AI models, particularly convolutional neural networks (CNNs), have significantly advanced edge and line detection. CNNs can be trained on large datasets of labeled images to learn complex patterns and features, including subtle or broken lines that traditional methods might miss. These models can adapt to variations in line thickness, gaps, and noise, making them especially useful for interpreting hand-drawn sketches or scanned diagrams. In practice, these networks output edge maps or segmentation masks highlighting the lines, which can then be refined further through vectorization or contour analysis.

Additionally, AI-powered approaches often combine both classical and deep learning techniques to achieve robust results. For instance, a hybrid system might use a CNN to generate an initial edge probability map and then apply traditional line fitting algorithms (such as the Hough transform) to detect continuous straight lines accurately. This synergy allows AI to handle diverse drawing styles and levels of detail, enabling applications in fields like architecture, patent illustration, and digital art restoration.

FIG. 11 shows an illustrative representation in which reference numerals are added either after the call-out lines have been added or simultaneously therewith, as representatively shown by reference numeral 1110. For example, it may be desirable for reference numerals not to overlap with any parts of the actual patent drawing lines. So, the AI-engine may analyze the call-out lines to ensure that sufficient space is allocated adjacent to call-out lines to accommodate the reference numerals. In some situations, the call-out lines may be changed, re-positioned, extended, shrunk, etc. in order to ensure sufficient space it allocated for the reference numerals.

Subsequent patent drawings 1105 in the patent drawing package may likewise be analyzed and configured. For example, the AI-engine may add reference numerals consistently to components throughout the drawings and dynamically adjust call-out lines positioning and type used, among other modifications, to create a fully complete patent drawing package. For example, FIGS. 2-10 within a drawing package may be from a different angle of the object in question, so the call-out line's positioning and reference numeral's positioning will likely need to be adjusted accordingly. Identified components, however, will be given consistent identification as a “call-out line” component and for a certain reference numeral. The AI-engine or system may utilize some of the line-identifying features described above. In some situations, the AI-engine may leverage additional angles of the object invention/product (e.g., the CAD file), and apply reference numerals to the components to ensure that the small amount of reference numerals are applied accurately. That way, the system does not need to rely on too distant angles to figure out the same component, but can rely on close-by adjustments, such as every two, five, or ten degree adjustments in all or various directions, among other degree-changes.

To propagate a user-requested annotation from one figure to every other figure that depicts the same part, the AI engine couples natural-language understanding with a persistent “component identity graph.” When the user inputs, for example, “Add a call-out line and reference numeral 105 to the latch in FIG. 1,” a language model parses the command and records a high-level edit: {target=‘latch’, action=‘add call-out’, numeral=105, source figure=1}. The vision module then isolates the latch in FIG. 1 by combining contour detection with a library of learned shape embeddings, confirms the user's intent visually (optionally asking for disambiguation if multiple candidates exist), and applies the graphical change in a vector layer. At the same moment, the latch's 2-D outline is mapped to an internal, view-agnostic token-either a unique feature ID from the underlying 3-D CAD assembly or, for raster-only workflows, a geometry signature generated via shape-context hashing and graph-matching algorithms. This token becomes the key in the component identity graph.

For every other drawing in the patent set (FIGS. 2-n), the engine iterates through detected components, compares their tokens to the graph, and flags any match as “same physical part, different view.” Because the reference-numeral registry now links that token to 105, the rendering subsystem automatically splices in an identically styled call-out line and numeral at an appropriate leader-line anchor in each view—taking view-dependent occlusion and scale into account. If the figures come from a parametric CAD model, the process is even simpler: the annotation is attached once to the 3-D feature, and the drawing generator re-projects it into every orthographic or isometric sheet.

Finally, a rule-based consistency checker verifies that (i) all occurrences of the latch now carry numeral 105, (ii) numeral 105 is not duplicated across unrelated parts, and (iii) drafting conventions (leader orientation, text height, spacing) remain uniform. If any discrepancies arise—say, a partial obstruction prevents clear leader placement—the system raises a “needs-review” flag for that sheet while still completing the rest. In this way, a single natural-language instruction cascades through an integrated pipeline of NLP parsing, component matching, and vector-graphics synthesis to keep every drawing synchronized with minimal human intervention.

In some situations, the user may click on certain parts or components to inform and educate the system where the part is. More input from the user regarding particular components may streamline or otherwise enhance the accuracy of the output. Such additional user input may be provided initially or responsive to the system's request based on some accuracy threshold assessment, such as a confidence check of 69% or lower may trigger the system to ask the user to provide more input for subsequent drawings, that is, for the user to identify a part or component with the reference numeral.

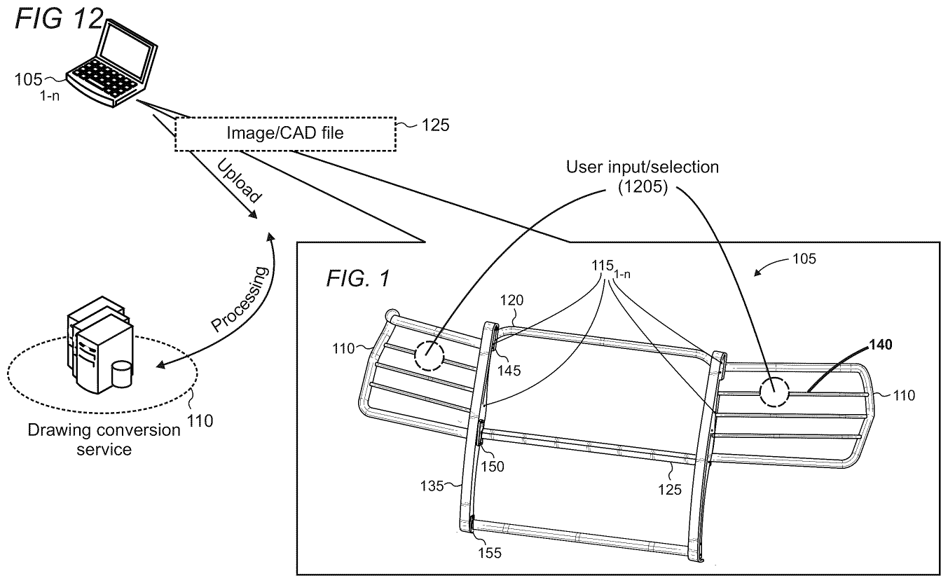

FIG. 12 shows an illustrative interactive environment in which a user operating the local computing device 105 can make a user selection 1205 at a component within a presentation, such as a preview, of the object/invention uploaded via a CAD or other image file 125. Once the user interactively selects, via some input mechanism on their computing device such as a mouse, voice-input, touch-screen input, etc., such input may be transmitted to the drawing conversion service 110 for processing. In this example, the drawing conversion service may add at least call-out lines and reference numerals to those selected components. This enables the user to select which components are worth identifying in the patent drawings and, if further downstream processing is performed (such as patent specification or claim drafting), such features are included in the AI-generated written disclosure. In the example shown in FIG. 12, reference numeral 140 was added and its associated call-out line in response to the user selection 1205.

User interaction can also be used for the user to customize other aspects of the drawings. For example, the user can select one or more lines for customization, such as selecting a solid black line and changing its line thickness, converting the line into a broken or dotted line, adjusting the line's length, deleting the line, among other changes. Other customizations are also possible.

In some situations, the drawing conversion service may present on the user's local device 105 options to change the generated patent drawing. Such as giving the user options of types of lines to choose from (broken, dotted, or solid lines), customizing the margins, moving or re-arranging parts of the drawing, giving the user options as to how they want reference numerals to be presented (e.g., increase by two, four, five, etc.), change or select the style of call-out lines (call-out line table 1005 in FIG. 10), among other options that the user can be presented with for the drawing conversion service to customize the drawings as per the specific user's preferences.

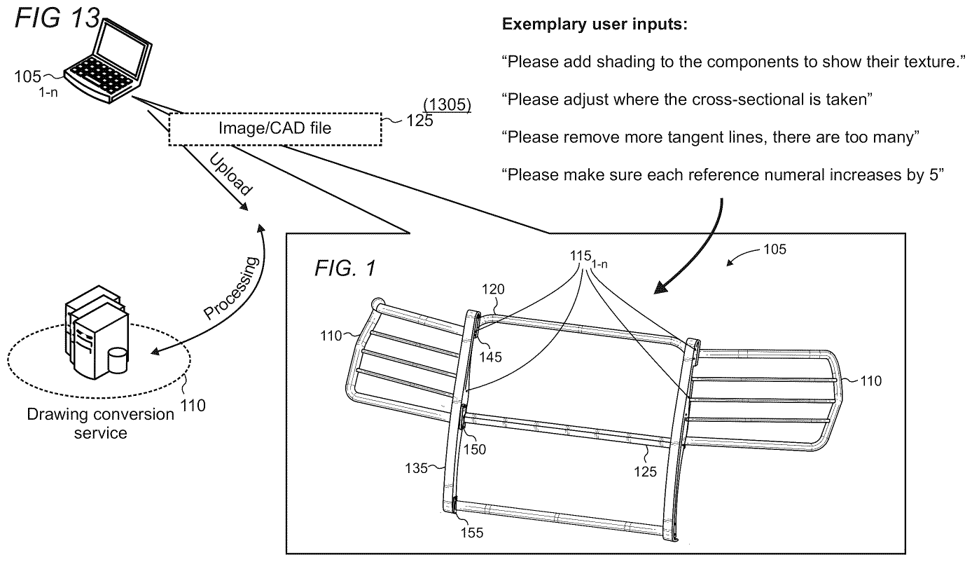

FIG. 13 shows an illustrative environment in which exemplary user inputs 1305 are input at the user computing device 105 for processing by the AI-engine. The AI-engine processes the user's input and creates a different output for the generated patent drawings. FIG. 13 shows exemplary user inputs to the AI-engine, instructing the AI-engine to make adjustments to the generated patent drawings outputs. While certain examples are shown in FIG. 13, other examples are also possible, which are unlimited by the capabilities of the AI-engine. In the examples shown in FIG. 13, the user can change characteristics of the drawings generated, changes to AI-forced changes (e.g., line shading), reference numerals, call-out lines, etc.

In one example implementation, the drawing conversion service 110 may be built as a multimodal AI pipeline that fuses computer-vision and natural-language-processing components. At the front end, the drawing is passed through a vision encoder-such as a convolutional neural network (CNN) or a Vision Transformer (ViT), that converts the raster image into a dense embedding capturing stroke locations, line-weight, and topology. In parallel, the user's request (“make the left gear larger,” “erase the center line,” “add a dashed border around the view”) is parsed by a large-language model (LLM) fine-tuned for command understanding; the LLM produces a structured intent that names target objects, desired geometric operations, and any stylistic constraints (e.g., line type, thickness).

Those two streams meet in a cross-modal alignment layer, similar to the CLIP architecture, where text tokens attend to image regions to pinpoint exactly which primitives need editing. Once the correspondence is established, a geometric reasoning module decides whether the change is vector-based (e.g., scaling a CAD entity) or raster-based (e.g., in-painting a freehand sketch). Vector edits are executed directly on the underlying path data using computational-geometry kernels, guaranteeing clean, resolution-independent results. Raster edits are handled by a diffusion or GAN-based generative model that has been trained on paired “before/after” sketches; it can redraw missing strokes, adjust hatching, or blend new elements seamlessly into the existing line art.

A final stage may be utilized that routes the updated drawing through a consistency checker driven by the same LLM to ensure the modification satisfies the original command and that drawing conventions (consistent line weights, correct reference numerals, no overlapping geometry) are preserved. By chaining vision encoding, NLP intent parsing, cross-modal grounding, and generative or parametric editing, the system delivers an interactive workspace where users can iteratively refine patent figures, technical schematics, or architectural sketches using plain English rather than low-level drawing tools.

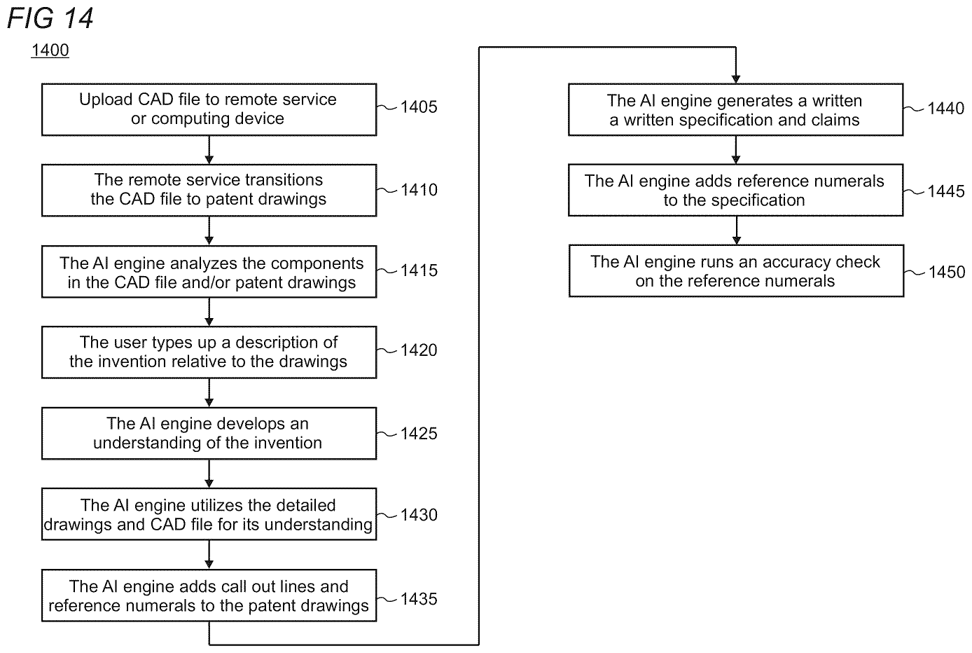

FIG. 14 shows an illustrative representation in which a process 1400 is shown in a flowchart. The various features in the flowchart may be performed by the user's local computing device 105, remote or local drawing conversion service 110, or a hybrid of the two. In step 1405, a user may upload a CAD file to the conversion service or other computing device. The CAD file may be a three-dimensional file of the mechanical product, however, other uploads of two-dimensional images may also be possible for processing.

In step 1410, the conversion service transitions the uploaded CAD or other image file into patent drawings. The patent drawings may be black and white line drawings that are in various formats, including PDT, vector-based, DXF, greyscale, etc. In step 1415, an AI-engine analyzes the component within the uploaded CAD file and/or the generated patent drawings. The AI-engine may analyze the three-dimensional or other uploaded image file or the generated black and white line drawings, in whichever format.

In step 1420, the user can type up a description of the invention at some AI-input interface to describe the invention or product encompassed in the CAD or other image file. This will enable the AI-engine to better understand what the invention and various components are. This step, as other are, is optional because in some situations the AI-engine may be able to determine the product's functionality on its own. However, having a user-description of the uploaded file's components can be helpful and enable a more accurate AI output.

In steps 1425 and 1430, the AI-engine may develop an understanding of the invention, either relying on the uploaded CAD/image file 125 or relying on the uploaded CAD/image file and the user's description. Relying on two inputs can improve the AI-engine's output because it is understanding a new invention's description, which can be otherwise difficult to be accurate if the AI-engine was solely relying on old technology from internet searches.

In step 1435, the AI engine adds call-out lines and reference numerals to the patent drawings (FIGS. 10-12). Thus, the AI-engine is able to analyze created patent drawings for future modification. In step 1440, the AI-engine generates a written description and claims based on the generated patent drawings and its understanding of the invention/product (steps 1425-1430). Thus, the AI-engine can juxtapose its user-input description to about the uploaded CAD/image file 125 and have a full understanding of the invention and its various components. In steps 1440 and 1445, relying on its digested and reasoned understanding, the AI-engine creates the specification and adds reference numerals thereto. Thus, the patent application's specification is able to properly reference specific components which have reference numerals.

In one exemplary embodiment to type up one or both of the written specification or claims, the AI engine that converts black-and-white patent drawings or uploaded CAD files into a narrative description may first tackles visual comprehension. For raster drawings, it enhances contrast, removes noise, and extracts edges; algorithms such as Canny filtering and probabilistic Hough transforms isolate strokes that are then vectorized into lines, arcs, and splines. In the CAD context, the engine ingests boundary-representation data directly, reading part hierarchies, feature trees, and metadata such as dimensions and tolerances. A geometric-reasoning layer groups these primitives into higher-order features—holes, bosses, housings, gears—using a library of learned shape templates distilled from thousands of prior-art figures.

Once geometric elements are identified, a multimodal transformer synthesizes meaning by aligning visual features with language tokens. If a user, such as the inventor or patent practitioner, supplies an outline (e.g., “a telescoping ladder with spring-loaded locks”), the text is embedded alongside spatial data so the model can disambiguate similar shapes and focus attention on functionally important regions. The transformer infers relationships. For example, member A slides relative to member B along axis X and is biased by spring C”, through spatial reasoning on contact surfaces and kinematic chains, while a mechanical-knowledge base supplies implicit components such as fasteners or bearings that drawings often omit but geometry demands.

The structured scene graph feeds a language model fine-tuned on a data set of granted patents or publications, which produces prose that meets USPTO conventions or requirements, or other foreign patent offices depending on the jurisdiction (e.g., Japanese Patent Office, EU Patent Office, etc.). The AI-engine inserts reference numerals (“ . . . as best shown in FIG. 3, latch 310 . . . ”) and follows the required cadence of broad overview, followed by detailed embodiments and alternatives. Where the user's seed text is terse, the model fleshes out inferred details—“The biasing member may preferably be a stainless-steel coil spring rated at approximately 20 N”—and pulls numeric ranges directly from CAD dimensions. A consistency checker verifies that every claimed element appears in at least one figure and that terminology remains uniform throughout the specification, claims, and drawings.

Together, these stages, visual understanding, semantic synthesis, and legal-grade language generation, transform raw imagery, supplemented when desired by a brief inventor narrative, into a richly detailed patent specification that dramatically accelerates and standardizes the drafting process.

Finally, in step 1450, the AI-engine or otherwise the drawing conversion service 110 runs an accuracy check of the reference numerals between the generated patent drawings and the specification. This check can include checking consistency among the drawings and also checking that reference numerals in the specification logically comport with the generated patent drawings.

Such a system enables a streamlined and, for example, a boilerplate patent application that a patent attorney can rely on. In some situations, the user-patent attorney may implement the present system at any of the various stages shown in FIG. 14 or throughout the drawings and system herein. For example, a user may want to use the check system at step 1450 for their patent application. Thus, the user may upload their own patent application drawings (such as from Visio, adobe illustrator, etc.) and their written specification (e.g., in WORD format) for comparison to ensure that their application is fully accurate.

In that regard, the present system may receive a user's completed patent application, drawings and written specification and claims, and verify that all reference numerals and descriptions are accurate. Specifically, checking that the reference numerals for specific components are consistent throughout the drawings and specification. Other accuracy checks can be performed by the same or an alternative/different AI-engine to identify errors or mistakes, which can be presented to the user either via text or other presentation on their user device 105.

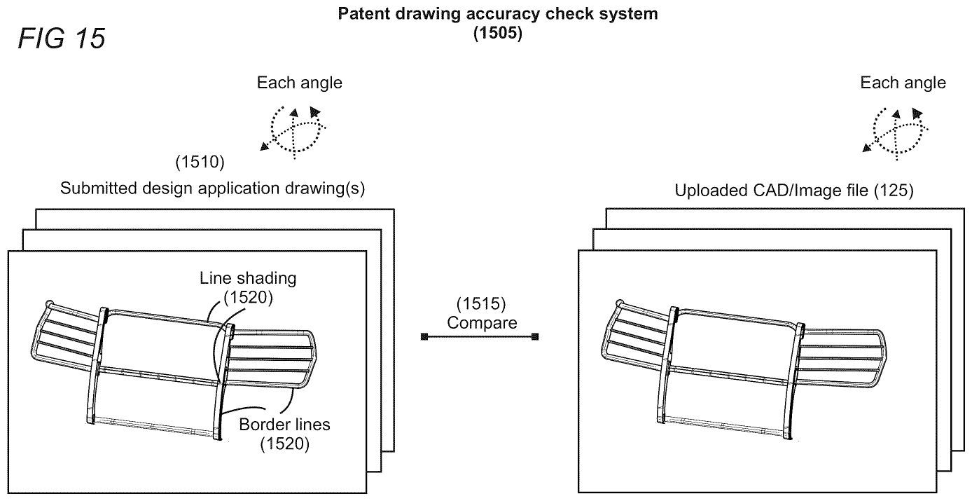

FIG. 15 shows an illustrative environment in which submitted design patent application drawings 1510 are compared 1515 to the uploaded CAD/image file 125 to provide a patent drawing accuracy check system 1505. While a design application drawings are shown in FIG. 15, utility or other patent application drawings depending on the context, such as a country's patent office rules, may also be applied. In this situation, for example, the drawing conversion service and an associated AI-engine may check border lines 1520 of various components within the Applicant's uploaded patent drawings, line shading 1520 within a patent drawing, if present, among other features. For example, line shading at the USPTO may be utilized to represent depth of a component—such depth can be checked for accuracy within the submitted application drawings 1510 since the uploaded CAD file includes all engineering features.

The submitted patent drawings in a patent application may be compared to a three-dimensional CAD file that the user submits either with the application or at some point later. Each angle of the file may be analyzed or at least angles that correspond with the submitted patent drawing angles. The user may provide some input to the system to alert it as to which angles were utilized for the submitted patent drawings.

Alternatively, AI may be utilized to compare each of the user's uploaded patent drawings and find a comparable angle for the accuracy comparison. For example, the AI engine may automatically generate multiple patent drawings of its own from the uploaded CAD file, and then compare those generated patent drawings to the patent Applicant's uploaded patent drawings. Alternatively, a more interactive back-and-forth may be performed between the Applicant's patent drawings and a comparison at the CAD file level so that only necessary patent drawings are generated.

Comparing the files may include a pre-processing of the uploaded CAD/Image file 125 and a generation of black and white or other patent drawings that can be used to compare to the submitted or otherwise other drawings 1510 that are being analyzed. Each submitted drawing 1510 and pre-processed drawing or otherwise uploaded CAD/image file 125 can be compared from like angles to verify that the submitted drawings are accurate and consistent. By comparing the submitted drawings to the engineered CAD file, the submitted patent application protected by the patent drawings can be verified for accuracy. Furthermore, relying on the CAD file provides additional protection at application-submission, so that the filer (Applicant and/or patent firm/attorney) is not constrained to patent drawings that are typically generated by a patent draftperson who is prone to mistakes. Even if there is a mistake, the Applicant can be assured that even if their black and white or other submitted patent drawings 1510 are inaccurate or problematic, that they properly submitted the engineering CAD file. This satisfies country-specific country laws because the CAD file in and of itself proves that the Applicant invented what it is they are submitting, and the Applicant is likewise helped because their potentially incorrect patent drawings submission is not fatal to their patent filing cause.

It should be understood that, while the remote drawing service 110 is discussed as performing the various functions herein, any computing device part of the process may possess the processing and configurations to perform such functionalities —whether wholly or partially. Thus, for example, the user computing device operating a local application instantiated on their device or via a web browser may be utilized to perform the functions described herein.

The drawing conversion service may present markups or insignia on some output file for the user to identify errors. For example, a color may be applied to the an output file so a patent Examiner can see the error with the patent drawings easily. The insignia may be a circle or box around an identified discrepancy, or alternatively lines may be highlighted with darker or colored alterations so the user can see a possible discrepancy. The output may be on patent drawings generated from the CAD file, or may be directly on the Applicant's patent drawings itself for review. Such automated actions can enhance the accuracy of patent examination processes and issued patents overall. Furthermore, such a system may be utilized internally by inventors or law firms to check their drawings before submission.

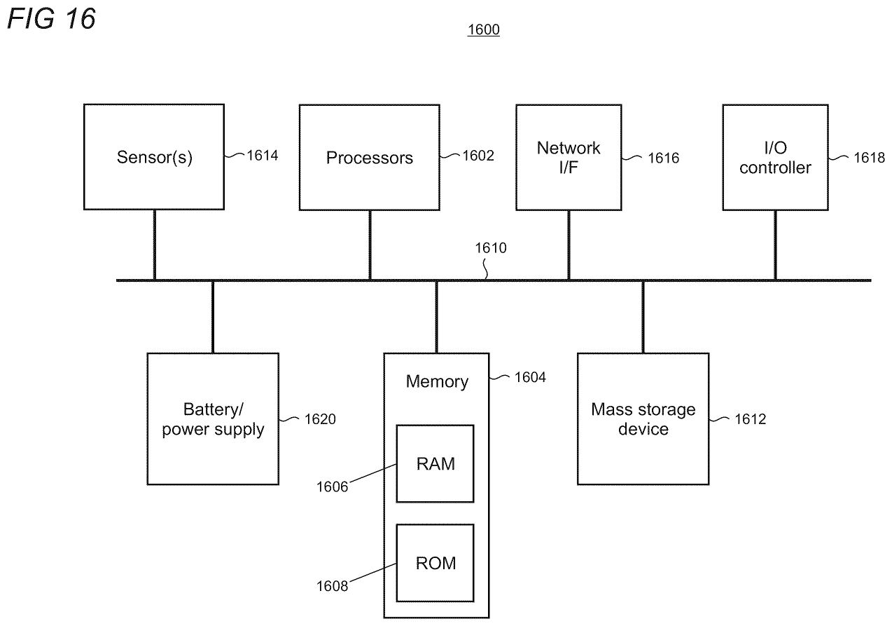

FIG. 16 shows an illustrative architecture 1600 for a client computing device such as a laptop computer or personal computer for the present automated generation of design patent drawings. The architecture 1600 illustrated in FIG. 16 includes one or more processors 1602 (e.g., central processing unit, dedicated Artificial Intelligence chip, graphics processing unit, etc.), a system memory 1604, including RAM (random access memory) 1606 and ROM (read only memory) 1608, and a system bus 1610 that operatively and functionally couples the components in the architecture 1600. A basic input/output system containing the basic routines that help to transfer information between elements within the architecture 1600, such as during startup, is typically stored in the ROM 1608. The architecture 1600 further includes a mass storage device 1612 for storing software code or other computer-executed code that is utilized to implement applications, the file system, and the operating system. The mass storage device 1612 is connected to the processor 1602 through a mass storage controller (not shown) connected to the bus 1610. The mass storage device 1612 and its associated computer-readable storage media provide non-volatile storage for the architecture 1600. Although the description of computer-readable storage media contained herein refers to a mass storage device, such as a hard disk or CD-ROM drive, it may be appreciated by those skilled in the art that computer-readable storage media can be any available storage media that can be accessed by the architecture 1600.

By way of example, and not limitation, computer-readable storage media may include volatile and non-volatile, removable and non-removable media implemented in any method or technology for storage of information such as computer-readable instructions, data structures, program modules, or other data. For example, computer-readable media includes, but is not limited to, RAM, ROM, EPROM (erasable programmable read only memory), EEPROM (electrically erasable programmable read only memory), Flash memory or other solid state memory technology, CD-ROM, DVD, HD-DVD (High Definition DVD), Blu-ray, or other optical storage, magnetic cassette, magnetic tape, magnetic disk storage or other magnetic storage device, or any other medium which can be used to store the desired information and which can be accessed by the architecture 1600.

According to various embodiments, the architecture 1600 may operate in a networked environment using logical connections to remote computers through a network. The architecture 1600 may connect to the network through a network interface unit 1616 connected to the bus 1610. It may be appreciated that the network interface unit 1616 also may be utilized to connect to other types of networks and remote computer systems. The architecture 1600 also may include an input/output controller 1618 for receiving and processing input from a number of other devices, including a keyboard, mouse, touchpad, touchscreen, control devices such as buttons and switches or electronic stylus (not shown in FIG. 16). Similarly, the input/output controller 1618 may provide output to a display screen, user interface, a printer, or other type of output device (also not shown in FIG. 16).

It may be appreciated that the software components described herein may, when loaded into the processor 1602 and executed, transform the processor 1602 and the overall architecture 1600 from a general-purpose computing system into a special-purpose computing system customized to facilitate the functionality presented herein. The processor 1602 may be constructed from any number of transistors or other discrete circuit elements, which may individually or collectively assume any number of states. More specifically, the processor 1602 may operate as a finite-state machine, in response to executable instructions contained within the software modules disclosed herein. These computer-executable instructions may transform the processor 1602 by specifying how the processor 1602 transitions between states, thereby transforming the transistors or other discrete hardware elements constituting the processor 1602.

Encoding the software modules presented herein also may transform the physical structure of the computer-readable storage media presented herein. The specific transformation of physical structure may depend on various factors in different implementations of this description. Examples of such factors may include, but are not limited to, the technology used to implement the computer-readable storage media, whether the computer-readable storage media is characterized as primary or secondary storage, and the like. For example, if the computer-readable storage media is implemented as semiconductor-based memory, the software disclosed herein may be encoded on the computer-readable storage media by transforming the physical state of the semiconductor memory. For example, the software may transform the state of transistors, capacitors, or other discrete circuit elements constituting the semiconductor memory. The software also may transform the physical state of such components in order to store data thereupon.

As another example, the computer-readable storage media disclosed herein may be implemented using magnetic or optical technology. In such implementations, the software presented herein may transform the physical state of magnetic or optical media, when the software is encoded therein. These transformations may include altering the magnetic characteristics of particular locations within given magnetic media. These transformations also may include altering the physical features or characteristics of particular locations within given optical media to change the optical characteristics of those locations. Other transformations of physical media are possible without departing from the scope and spirit of the present description, with the foregoing examples provided only to facilitate this discussion.

The architecture 1600 may further include one or more sensors 1614 or a battery or power supply 1620. The sensors may be coupled to the architecture to pick up data about an environment or a component, including temperature, pressure, etc. Exemplary sensors can include a thermometer, accelerometer, smoke or gas sensor, pressure sensor (barometric or physical), light sensor, ultrasonic sensor, gyroscope, among others. The power supply may be adapted with an AC power cord or a battery, such as a rechargeable battery for portability.

In light of the above, it may be appreciated that many types of physical transformations take place in the architecture 1600 in order to store and execute the software components presented herein. It also may be appreciated that the architecture 1600 may include other types of computing devices, including wearable devices, handheld computers, embedded computer systems, smartphones, PDAs, and other types of computing devices known to those skilled in the art. It is also contemplated that the architecture 1600 may not include all of the components shown in FIG. 16, may include other components that are not explicitly shown in FIG. 16, or may utilize an architecture completely different from that shown in FIG. 16.

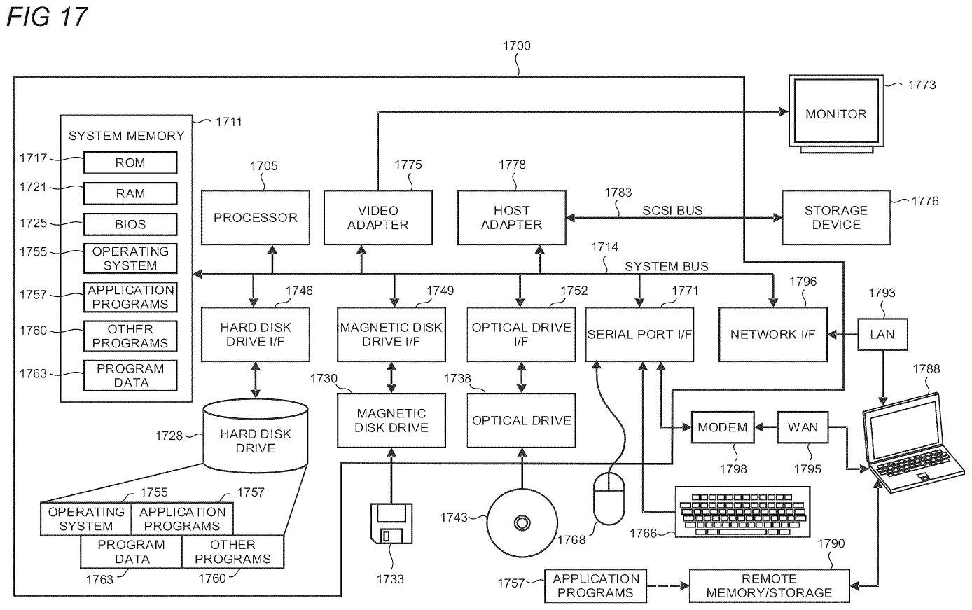

FIG. 17 is a simplified block diagram of an illustrative computer system 1700 such as a PC or server with which the present automated generation of design patent drawings may be implemented. Computer system 1700 includes a processor 1705, a system memory 1711, and a system bus 1714 that couples various system components including the system memory 1711 to the processor 1705. The system bus 1714 may be any of several types of bus structures including a memory bus or memory controller, a peripheral bus, or a local bus using any of a variety of bus architectures.

The system memory 1711 includes read only memory (ROM) 1717 and random-access memory (RAM) 1721. A basic input/output system (BIOS) 1725, containing the basic routines that help to transfer information between elements within the computer system 1700, such as during startup, is stored in ROM 1717. The computer system 1700 may further include a hard disk drive 1728 for reading from and writing to an internally disposed hard disk (not shown), a magnetic disk drive 1730 for reading from or writing to a removable magnetic disk 1733 (e.g., a floppy disk), and an optical disk drive 1738 for reading from or writing to a removable optical disk 1743 such as a CD (compact disc), DVD (digital versatile disc), or other optical media. The hard disk drive 1728, magnetic disk drive 1730, and optical disk drive 1738 are connected to the system bus 1714 by a hard disk drive interface 1746, a magnetic disk drive interface 1749, and an optical drive interface 1752, respectively. The drives and their associated computer-readable storage media provide non-volatile storage of computer-readable instructions, data structures, program modules, and other data for the computer system 1700.

Although this illustrative example includes a hard disk, a removable magnetic disk 1733, and a removable optical disk 1743, other types of computer-readable storage media which can store data that is accessible by a computer such as magnetic cassettes, Flash memory cards, digital video disks, data cartridges, random access memories (RAMs), read only memories (ROMs), and the like may also be used in some applications of the present automated generation of design patent drawings. In addition, as used herein, the term computer-readable storage media includes one or more instances of a media type (e.g., one or more magnetic disks, one or more CDs, etc.). For purposes of this specification and the claims, the phrase “computer-readable storage media” and variations thereof, are intended to cover non-transitory embodiments, and do not include waves, signals, and/or other transitory and/or intangible communication media.

A number of program modules may be stored on the hard disk, magnetic disk 1733, optical disk 1743, ROM 1717, or RAM 1721, including an operating system 1755, one or more application programs 1757, other program modules 1760, and program data 1763. A user may enter commands and information into the computer system 1700 through input devices such as a keyboard 1766 and pointing device 1768 such as a mouse. Other input devices (not shown) may include a microphone, joystick, game pad, satellite dish, scanner, trackball, touchpad, touchscreen, touch-sensitive device, voice-command module or device, user motion or user gesture capture device, or the like. These and other input devices are often connected to the processor 1705 through a serial port interface 1771 that is coupled to the system bus 1714, but may be connected by other interfaces, such as a parallel port, game port, or universal serial bus (USB). A monitor 1773 or other type of display device is also connected to the system bus 1714 via an interface, such as a video adapter 1775. In addition to the monitor 1773, personal computers typically include other peripheral output devices (not shown), such as speakers and printers. The illustrative example shown in FIG. 17 also includes a host adapter 1778, a Small Computer System Interface (SCSI) bus 1783, and an external storage device 1776 connected to the SCSI bus 1783.

The computer system 1700 is operable in a networked environment using logical connections to one or more remote computers, such as a remote computer 1788. The remote computer 1788 may be selected as another personal computer, a server, a router, a network PC, a peer device, or other common network node, and typically includes many or all of the elements described above relative to the computer system 1700, although only a single representative remote memory/storage device 1790 is shown in FIG. 17. The logical connections depicted in FIG. 17 include a local area network (LAN) 1793 and a wide area network (WAN) 1795. Such networking environments are often deployed, for example, in offices, enterprise-wide computer networks, intranets, and the Internet.

When used in a LAN networking environment, the computer system 1700 is connected to the local area network 1793 through a network interface or adapter 1796. When used in a WAN networking environment, the computer system 1700 typically includes a broadband modem 1798, network gateway, or other means for establishing communications over the wide area network 1795, such as the Internet. The broadband modem 1798, which may be internal or external, is connected to the system bus 1714 via a serial port interface 1771. In a networked environment, program modules related to the computer system 1700, or portions thereof, may be stored in the remote memory storage device 1790. It is noted that the network connections shown in FIG. 17 are illustrative and other means of establishing a communications link between the computers may be used depending on the specific requirements of an application of the present automated generation of design patent drawings.

Various exemplary embodiments are disclosed herein. In one exemplary embodiment, disclosed is a computing device, comprising: one or more processors; and one or more hardware-based memory devices storing computer-executable instructions which, when executed by the one or more patent drawings, causes the computing device to: receive a CAD file; generate one or more patent drawings using the received CAD file; and apply an artificial intelligence (AI)-engine to the generated one or more patent drawings, in which the AI-engine makes an adjustment to the one or more patent drawings.

In a further example, the CAD file is any one or more of a . stp file or . stl file. In another example, the adjustment to the one or more patent drawings is adding call-out lines. In another example, the adjustment to the one or more patent drawings is adding reference numerals. In another example, the generated one or more patent drawings include multiple patent drawings, and the added reference numerals and call-out lines are consistently applied to components throughout the multiple patent drawings. As another example, the executed instructions are further configured to enable user-interactive adjustments to the generated one or more patent drawings. As another example, the executed instructions are further configured to receive input from a user, and the AI-engine is configured to utilize NLP (natural language processing) to make corresponding changes to the generated one or more patent drawings. In another example, the executed instructions are further configured to receive input from a user, and the input is an interaction with a portion of an object from the CAD file that is presented on a user computing device. In another example, the computing device is a remote drawing service or a user's local computing device.

In another exemplary embodiment, disclosed is a method performed by a computing device, comprising: receiving a CAD file; generating one or more patent drawings using the received CAD file; and applying an artificial intelligence (AI)-engine to the generated one or more patent drawings, in which the AI-engine makes an adjustment to the one or more patent drawings.

As another example, the CAD file is any one or more of a .stp file or .stl file. In another example, the adjustment to the one or more patent drawings is adding call-out lines. In another example, the adjustment to the one or more patent drawings is adding reference numerals. As another example, the generated one or more patent drawings include multiple patent drawings, and the added reference numerals and call-out lines are consistently applied to components throughout the multiple patent drawings. As another example, the executed instructions are further configured to enable user-interactive adjustments to the generated one or more patent drawings.

In an other exemplary embodiment, disclosed is one or more hardware-based non-transitory memory devices disposed within a remote service storing computer-executable instructions which, when executed by a remote service, causes the remote service to: receive a CAD file; generate one or more patent drawings using the received CAD file; and apply an artificial intelligence (AI)-engine to the generated one or more patent drawings, in which the AI-engine makes an adjustment to the one or more patent drawings.

In another example, the CAD file is any one or more of a .stp file or .stl file. As another example, the adjustment to the one or more patent drawings is adding call-out lines. As another example, the adjustment to the one or more patent drawings is adding reference numerals. As another example, the generated one or more patent drawings include multiple patent drawings, and the added reference numerals and call-out lines are consistently applied to components throughout the multiple patent drawings.

Although the subject matter has been described in language specific to structural features and/or methodological acts, it is to be understood that the subject matter defined in the appended claims is not necessarily limited to the specific features or acts described above. Rather, the specific features and acts described above are disclosed as example forms of implementing the claims.

1. A computing device, comprising:
one or more processors; and
one or more hardware-based memory devices storing computer-executable instructions which, when executed by the one or more patent sprocessors, causes the computing device to:
receive a CAD (Computer Aided Design ) file;
responsive to receiving the CAD file, present a first view of the CAD file, wherein the first view is based on an autonomously set position by a conversion service, in which the autonomously set position includes presenting all portions within the first view of a two-dimensional version of an object within the CAD file;
convert the first view of the CAD file into a first different file type from the CAD file;
alter the first view to a variety of different views, and after each new view, convert the new view into a same of the first different file type from the CAD file, wherein the variety of different views and new views are based on further autonomously set positions by the conversion service; and
after converting all of the variety of different views into the first different file types from the CAD file, continue to present and alter multiple views of the CAD file to generate a second set of files that are of a second different file type from the CAD file and the first different file type.

2. The computing device of claim 1, wherein the first or second different file types is a PDF file.

3. The computing device of claim 1, wherein the first or second different file types is a vector file.

4. The computing device of claim 1, wherein the first or second different file types is a greyscale file.

5. A method performed by a computing device, comprising:
receiving a CAD (Computer Aided Design) file;
responsive to receiving the CAD file, presenting a first view of the CAD file, wherein the first view is based on an autonomously set position by a conversion service, in which the autonomously set position includes presenting all portions within the first view of a two-dimensional version of an object within the CAD file;
converting the first view of the CAD file into a first different file type from the CAD file;
altering the first view to a variety of different views, and after each new view, convert the new view into a same of the first different file type from the CAD file, wherein the variety of different views and new views are based on further autonomously set positions by the conversion service; and
after converting all of the variety of different views into the first different file types from the CAD file, continuing to present and alter multiple views of the CAD file to generate a second set of files that are of a second different file type from the CAD file and the first different file type.

6. The method of claim 5, wherein the first or second different file types is a PDF file.

7. The method of claim 5, wherein the first or second different file types is a vector file.

8. The method of claim 5, wherein the first or second different file types is a greyscale file.

9. One or more hardware-based non-transitory memory devices disposed within a remote service storing computer-executable instructions which, when executed by a remote service, causes the remote service to:
receive a CAD (Computer Aided Design) file;
responsive to receiving the CAD file, present a first view of the CAD file, wherein the first view is based on an autonomously set position by a conversion service, in which the autonomously set position includes presenting all portions within the first view of a two-dimensional version of an object within the CAD file;
convert the first view of the CAD file into a first different file type from the CAD file;
altering the first view to a variety of different views, and after each new view, convert the new view into a same of the first different file type from the CAD file, wherein the variety of different views and new views are based on further autonomously set positions by the conversion service;
after converting all of the variety of different views into the first different file types from the CAD file, continue to present and alter multiple views of the CAD file to generate a second set of files that are of a second different file type from the CAD file and the first different file type.

10. The one or more hardware-based memory devices of claim 9, the first or second different file types is a PDF file.

11. The one or more hardware-based memory devices of claim 9, wherein the first or second different file types is a vector file.

12. The one or more hardware-based memory devices of claim 9, wherein the first or second different file types is a greyscale file.
